(19) United States
(12) Patent Application Publication
(10) Pub. No.: US 2014/0363915 A1
(43) Pub. Date: Dec. 11, 2014

(54) NEGATIVE PHOTOSENSITIVE RESIN COMPOSITION AND APPLICATION THEREOF

(71) Applicant: CHI MEI CORPORATION, TAINAN CITY (TW)

(72) Inventor: Yu-Jie Tsai, Tainan City (TW)

(21) Appl. No.: 14/301,340

(22) Filed: Jun. 11, 2014

(30) Foreign Application Priority Data
Jun. 11, 2013 (TW) 102120774

(51) Int. Cl. G03F 7/038; H01L 51/56; H01L 51/00; H01L 33/00

(52) U.S. Cl. CPC G03F 7/038; H01L 33/005; H01L 51/56; H01L 51/0023; H01L 51/0002; H01L 2933/0016
USPC 438/46; 430/281.1; 430/322; 438/22

(57) ABSTRACT

A negative photosensitive resin composition including a novolac resin (A), a photoacid generator (B), a basic compound (C), a cross-linking agent (D), and a solvent (E) is provided. The novolac resin (A) includes a hydroxy-type novolac resin (A-1) and a xylenol-type novolac resin (A-2). The hydroxy-type novolac resin (A-1) is synthesized by polycondensing a hydroxybenzaldehyde compound and an aromatic hydroxy compound. The xylenol-type novolac resin (A-2) is synthesized by polycondensing an aldehyde compound and a xylenol compound.

### CROSS-REFERENCE TO RELATED APPLICATION

This application claims the priority benefit of Taiwan application serial no. 102120774, filed on Jun. 11, 2013. The entirety of the above-mentioned patent application is hereby incorporated by reference herein and made a part of this specification.

### FIELD OF THE APPLICATION

The invention is directed to a photosensitive resin composition, and more particularly, to a negative photosensitive resin composition.

### DESCRIPTION OF RELATED ART

In recent years, following the development of the semiconductor industry, liquid crystal displays (LCDs) and organic electro-luminescence displays (OELDs), the demand of size reduction arises and the photolithography processes become very important issues. In the photolithography process, the miniaturization of the pattern(s) is required to attain the purpose of size reduction.

Generally, in a semiconductor manufacturing process, a metallic pattern may be manufactured with a lift-off method. Steps of the lift-off method are as follows. Firstly, a photoresist pattern is formed on a substrate. Next, a metal layer is vapor deposited on the substrate formed with the photoresist pattern thereon. Finally, the photoresist pattern and the metal layer formed on the photoresist pattern are lifted-off to form the metallic pattern. In the lift-off method, since a cross-section of the photoresist pattern is reversed tapered shape, the metal layer covering on the substrate and the metal layer covering on the photoresist pattern are discrete, and are easily to be removed. Noteworthily, the photoresist pattern has poor heat resistance and high water absorption problems.

On the other hand, in the organic electro-luminescence displays, the photoresist pattern is often used as a spacer on a first electrode layer, and an organic EL medium is coated on the first electrode layer exposed by the spacer to form a pixel layer. Next, the metal layer is vapor deposited on the overall surface of the spacer and the pixel layer to form a second electrode layer located on the pixel layer. Noteworthily, since an organic light emitting element are easily damaged by ingredients such as moisture and solvent, a material with low water absorption is more desirable to be used as the spacer. In other words, in order to remove the residual moisture and solvent in the spacer, deaeration treatments are often performed to the spacer and other organic light emitting elements under a high temperature. Nevertheless, the spacer is thereby deformed, and becomes unfavorable for use.

Japanese Patent No. 3320397 discloses a method for forming a reversed tapered shape photoresist pattern, which uses a bisphenol compound as a negative photosensitive resin composition to form the photoresist pattern with the said negative photosensitive resin composition. As a result, a metallic pattern may then be formed on the photoresist pattern via an evaporation method, and the photoresist pattern is also able to be formed into a spacer having a favorable heat resistance and low water absorption. However, when using the said negative photosensitive resin composition to form the photoresist pattern, the resulting photoresist pattern is presented with problems of having a poor strippability with the substrate and being intolerant to the evaporation process.

As such, it is in need to develop a negative photosensitive resin composition adapted to form a photoresist pattern having a favorable strippability with the substrate and being tolerant to the evaporation process.

### SUMMARY OF THE APPLICATION

The invention provides a negative photosensitive resin composition being used to form a photoresist pattern having a favorable strippability and tolerance to evaporation process with a substrate.

The invention provides a negative photosensitive resin composition including a novolac resin (A), a photoacid generator (B), a basic compound (C), a cross-linking agent (D) and a solvent (E). The novolac resin (A) includes a hydroxy-type novolac resin (A-1) and a xylenol-type novolac resin (A-2). The hydroxy-type novolac resin (A-1) is synthesized by polycondensing a hydroxybenzaldehyde compound and an aromatic hydroxy compound. The xylenol-type novolac resin (A-2) is synthesized by polycondensing an aldehyde compound and a xylenol compound.

In an embodiment of the invention, the photoacid generator (B) may include an onium salt compound, a halogen-containing compound, a sulfone compound, a sulfonic acid compound, a sulfonimide compound or a combination thereof.

In an embodiment of the invention, the basic compound (C) may include an aliphatic primary amine, an aliphatic secondary amine, an aliphatic tertiary amine, an amino alcohol, an aromatic amine, a quaternary ammonium hydroxide, an alicyclic amine alicyclic amine or a combination thereof.

In an embodiment of the invention, wherein based on 100 parts by weight of the novolac resin (A), a usage amount of the photoacid generator (B) is 0.1 to 5 parts by weight, a usage amount of the basic compound (C) is 0.1 to 5 parts by weight, a usage amount of the cross-linking agent (D) is 5 to 50 parts by weight, and a usage amount of the solvent (E) is 100 to 1000 parts by weight.

In an embodiment of the invention, wherein based on a total usage amount of the hydroxy-type novolac resin (A-1) and the xylenol-type novolac resin (A-2) being 100 weight %, a usage amount of the hydroxy-type novolac resin (A-1) is 10 weight % to 80 weight %, and a usage amount of the xylenol-type novolac resin (A-2) is 90 weight % to 20 weight %.

The invention further provides a method for forming a photoresist pattern including the following steps. Firstly, the aforementioned negative photosensitive resin composition is coated on a substrate. Next, a processing step is performed to the negative photosensitive resin composition so as to from the photoresist pattern.

In an embodiment of the invention, wherein the aforementioned photoresist pattern is a spacer.

The invention further provides a method for forming a metallic pattern including the following steps. Firstly, the aforementioned photoresist pattern is formed on a substrate. Next, a metal layer is formed on the substrate and the photoresist pattern. Finally, the photoresist pattern and metal layer on the photoresist pattern are removed so as to form the metallic pattern.

The invention also provides a method for manufacturing a light emitting diode grain including the following steps. Firstly, a semiconductor layer is formed on a substrate. Next, a metallic pattern is formed on at least one side of the semiconductor layer for being an electrode layer, wherein the metallic pattern is formed by using the aforementioned method.

The invention provides a method for forming an organic light emitting diode display device including the following steps. Firstly, a first electrode layer is formed on a substrate. Next, the aforementioned negative photosensitive resin composition is coated on the substrate. Then, the processing step is formed to the negative photosensitive resin composition so as to form the spacer. Afterward, an organic layer is formed within a region defined by the spacer. Finally, a second electrode layer is formed on the organic layer.

According to the foregoing, the novolac resin (A) of the negative photosensitive resin composition including the hydroxy-type novolac resin (A-1) and the xylenol-type novolac resin (A-2) may effectively improve the problems of having a poor strippability between the photoresist pattern and the substrate, and the photoresist pattern being intolerant to the evaporation process, when the photoresist pattern is formed by a conventional negative photosensitive resin composition.

In order to make the aforementioned and other features and advantages of the present application more comprehensible, several embodiments accompanied with figures are described in detail below.

### BRIEF DESCRIPTION OF THE DRAWINGS

The accompanying drawings are included to provide a further understanding of the application, and are incorporated in and constitute a part of this specification. The drawings illustrate embodiments of the application and, together with the description, serve to explain the principles of the application.

FIG. 1A to FIG. 1C are schematic diagrams illustrating a light emitting diode grain according to an embodiment of the invention.

FIG. 2A to FIG. 2C are schematic diagrams illustrating a method for manufacturing an organic light emitting diode display device according to an embodiment of the invention.

### DETAILED DESCRIPTION OF DISCLOSED EMBODIMENTS

### Preparation of a Negative Photosensitive Resin Composition

The invention provides a negative photosensitive resin composition including a novolac resin (A), a photoacid generator (B), a basic compound (C), a cross-linking agent (D) and a solvent (E). In addition, if required, the negative photosensitive resin composition may further include an additive (F). In the following below, detail descriptions regarding each ingredient of the negative photosensitive resin composition of the invention are provided.

Novolac Resin (A)

The novolac resin (A) includes a hydroxy-type novolac resin (A-1) and a xylenol-type novolac resin (A-2).

Hydroxy-Type Novolac Resin (A-1)

The hydroxy-type novolac resin (A-1) is obtained through a condensation reaction of a hydroxybenzaldehyde compound and an aromatic hydroxy compound with a presence of acidic catalyst.

Specific examples of the hydroxybenzaldehyde compound include: o-hydroxybenzaldehyde, m-hydroxybenzaldehyde and p-hydroxybenzaldehyde or other hydroxybenzaldehyde compound of the likes; 2,3-dihydroxybenzaldehyde, 2,4-dihydroxybenzaldehyde, 2,5-dihydroxybenzaldehyde, 3,4-dihydroxybenzaldehyde and 3,5-dihydroxybenzaldehyde or other dihydroxybenzaldehyde compound of the likes; 2,3,4-trihydroxybenzaldehyde, 2,4,5-trihydroxybenzaldehyde, 2,4,6-trihydroxybenzaldehyde, 3,4,5-trihydroxybenzaldehyde or other trihydroxybenzaldehyde compound of the likes; o-hydroxymethylbenzaldehyde, m-hydroxymethylbenzaldehyde, p-hydroxymethylbenzaldehyde or other hydroxyalkylbenzaldehyde compound of the likes, or a combination thereof. The hydroxybenzaldehyde compound may be used alone or in multiple combinations. The hydroxybenzaldehyde compound is preferably o-hydroxybenzaldehyde, m-hydroxybenzaldehyde, p-hydroxybenzaldehyde, 2,3-dihydroxybenzaldehyde, 2,4-dihydroxybenzaldehyde, 3,4-dihydroxybenzaldehyde, 2,3,4-trihydroxybenzaldehyde or o-hydroxymethylbenzaldehyde.

Specific examples of the aromatic hydroxy compound include: phenol; m-cresol, p-cresol, o-cresol or other cresol of the likes; 2,3-dimethylphenol, 2,5-dimethylphenol, 3,5-dimethylphenol, 3,4-dimethylphenol or other xylenol of the likes; m-ethylphenol, p-ethylphenol, o-ethylphenol, 2,3,5-trimethylphenol, 2,3,5-trimethylphenol, 4-t-butylphenol, 3-t-butylphenol, 2-t-butylphenol, 2-t-butyl-4-methylphenol, 2-t-butyl-5-methylphenol, 6-t-butyl-3-methylphenol or other alkyl phenol of the likes; p-methoxyphenol, m-methoxyphenol, p-ethoxyphenol, m-ethoxyphenol, p-propoxyphenol, m-propoxyphenol or other alkoxy phenol of the likes; o-isopropenyl phenol, p-isopropenyl phenol, 2-methyl-4-isopropenyl phenol, 2-ethyl-4-isopropenyl phenol or other isopropenyl phenol of the likes; phenyl phenol of the aryl phenol; and 4,4′-dihydroxy biphenyl, bisphenol A, resorcinol, hydroquinone, 1,2,3-pyrogallol or other polyhydroxyphenol of the likes, or a combination thereof. The aromatic hydroxy compound may be used alone or in multiple combinations. The aromatic hydroxy compound is preferably o-cresol, m-cresol, p-cresol, 2,5-dimethylphenol, 3,5-dimethylphenol or 2,3,5-trimethylphenol.

Specific examples of the acidic catalyst include: hydrochloric acid, sulfuric acid, methanoic acid, acetic acid, oxalic acid, p-toluenesulfonic acid or the like, or a combination thereof.

Xylenol-Type Novolac Resin (A-2)

The xylenol-type novolac resin (A-2) is obtained is obtained through a condensation reaction of a naldehyde compound and a xylenol compound with a presence of an acidic catalyst, wherein the acidic catalyst used herein may be the acidic catalyst used for synthesizing the hydroxy-type novolac resin (A-1).

Specific examples of the aldehyde compound include: formaldehyde, paraformaldehyde, trioxane, acetaldehyde, propionaldehyde, butyraldehyde, trimethylacetaldehyde, acrolein, crotonaldehyde, cyclohexanecarbaldehyde, furfural, furylacrolei, benzaldehyde terephthal aldehyde, phenylacetaldehyde, α-phenylpropylaldehyde, β-phenylpropylaldehyde, o-methylbenzaldehyde, m-methylbenzaldehyde, p-methylbenzaldehyde, o-chlorobenzaldehyde, m-chlorobenzaldehyde, p-chlorobenzaldehyde, cinnamaldehyde or the like, or a combination thereof. The aldehyde compound may be used alone or in multiple combinations. The aldehyde compound is preferably formaldehyde or benzaldehyde.

Specific examples of the xylenol compound include: 2,3-dimethylphenol, 2,5-dimethylphenol, 3,5-dimethylphenol, 3,4-dimethylphenoll or a combination thereof.

Based on a total usage amount of the hydroxy-type novolac resin (A-1) and the xylenol-type novolac resin (A-2) being 100 weight %, a usage amount of the hydroxy-type novolac resin (A-1) is 10 weight % to 80 weight %, and a usage amount of the of xylenol-type novolac resin (A-2) is 90 weight % to 20 weight %. Preferably, the usage amount of the hydroxy-type novolac resin (A-1) is 15 weight % to 85 weight %, and the usage amount of the xylenol-type novolac resin (A-2) is 85 weight % to 15 weight %. More preferably, the usage amount of the hydroxy-type novolac resin (A-1) is 20 weight % to 80 weight %, and the usage amount of the xylenol-type novolac resin (A-2) is 80 weight % to 20 weight %.

Noteworthily, since the photoresist pattern formed by the negative photosensitive resin composition including the hydroxy-type novolac resin (A-1) has a favorable strippability with the substrate, and the photoresist pattern formed by the negative photosensitive resin composition including the xylenol-type novolac resin (A-2) has a favorable degree of tolerance to the evaporation process thereof; therefore, if the negative photosensitive resin composition unable to use the hydroxy-type novolac resin (A-1) or the xylenol-type novolac resin (A-2), the obtained photoresist pattern formed by the negative photosensitive resin composition has a poor strippability and a problem of being intolerant to evaporation process.

Under the premise that the above objectives may be achieved, the novolac resin (A) of the negative photosensitive resin composition of the invention may further include other novolac resin (A-3). The other novolac resin (A-3) is obtained through the condensation reaction of an aldehyde compound and an aromatic hydroxy compound with the presence of the aforementioned acidic catalyst. The aldehyde compound and the aromatic hydroxy compound are the exemplary compounds listed above, but a structure of the other novolac resin (A-3) is different from structures of the hydroxy-type novolac resin (A-1) and the xylenol-type novolac resin (A-2). The other novolac resin (A-3) may be used alone or in multiple combinations.

### Photoacid Generator (B)

The photoacid generator (B) is a compound capable of producing acids after light irradiation. In the invention, the photoacid generator (B) is being used as a catalyst for performing a polymerization reaction between the novolac resin (A) and the following cross-linking agent (D). Specifically, the photoacid generator (B), for example, is an onium salt compound, a halogen-containing compound, a sulfone compound, a sulfonic acid compound, a sulfonimide compound or a combination thereof.

The onium salt compound, for example, is an iodonium salt, a sulfonium salt, a phosphonium salt; a diazonium salt, a pyridinium salt or the like. Specific examples of the onium salt compound include: diphenyliodonium trifluoromethanesulfonate, diphenyliodonium p-toluenesulfonate, diphenyliodonium hexafluoroantimonate, diphenyliodonium hexafluorophosphate, diphenyliodonium tetrafluoroborate, triphenylsulfonium trifluoromethanesulfonate, triphenylsulfonium p-toluenesulfonate, triphenylsulfonium hexafluoroantimonate, 4-t-butylphenyldiphenylsulfonium trifluoromethanesulfonate, 4-t-butylphenyldiphenylsulfonium p-toluenesulfonate, 4,7-di-n-butoxynaphthyltetrahydrothiophenium trifluoromethanesulfonate or a combination thereof.

In addition, the onium salt compound may also be cyclohexylmethyl(2-oxocyclohexyl)sulfonium trifluoromethanesulfonate, dicyclohexyl(2-oxocyclohexyl)sulfonium trifluoromethanesulfonate, (2-oxocyclohexyl)(2-norbornyl)sulfonium trifluoromethanesulfonate, 2-cyclohexylsulfonyl cyclohexanone, dimethyl(2-oxocyclohexyl)sulfonium trifluoromethanesulfonate, N-hydroxy succinimide trifluoromethanesulfonate, phenyl p-toluenesulfonate or a combination thereof.

The halogen-containing compound, for example, includes a haloalkyl-containing hydrocarbon compound or a haloalkyl-containing heterocyclic compound. Specific examples of the halogen-containing compound include: 1,10-dibromo-n-decane, 1,1-bis(4-chlorophenyl)-2,2,2-trichloroethane, phenyl-bis(trichloromethyl)-s-triazine, 4-methoxyphenyl bis(trichloromethyl)-s-triazine, styryl bis(trichloromethyl)-s-triazine, naphthyl bis(trichloromethyl)-s-triazine, 2,4-bis(trichloromethyl)-6-p-methoxystyryl-s-triazine, TAZ-110 or the like of s-triazine, or a combination thereof.

In addition, the halogen-containing compound may also be tris(2,3-dibromopropyl)phosphate, tris(2,3-dibromo-3-chloropropyl) phosphate, tetrabromochlorobutane, 2-[2-(3,4-dimethoxyphenyl) ethenyl]-4,6-bis(trichloromethyl)-s-triazine, 2-[2-(4-methoxypheny) ethenyl]-4,6-bis(trichloromethyl)-s-triazine, hexachlorobenzene, hexabromobenzene, hexabromocyclododecane, hexabromocyclododecene, hexabromobiphenyl, allyltribromophenyl ether, tetrachlorobisphenol A, tetrabromobisphenol A, bis(chloroethyl)ether of tetrachlorobisphenol A, bis(bromoethyl)ether of tetrabromobisphenol A, bis(2,3-dichloropropyl)ether of bisphenol A, bis(2,3-dibromopropyl)ether of bisphenol A, bis(2,3-dichloropropyl)ether of tetrachlorobisphenol A, bis(2,3-dibromopropyl)ether of tetrabromobisphenol A, bis(chloroethyl)ether of the tetrachlorobisphenol S, tetrabromobisphenol S, tetrachlorobisphenol S, bis(bromoethyl)ether of tetrabromobisphenol S, bis(2,3-dichloropropyl)ether of the bisphenol S, bis(2,3-dichloropropyl)ether of the bisphenol S, tris(2,3-dibromopropyl) isocyanurate, 2,2-bis(4-hydroxy-3,5-dibromophenyl)propane, 2,2-bis(4-(2-hydroxyethoxy)-3,5-dibromophenyl)propane or the like (halogen series flame retardant).

The sulfone compound, for example, is a β-ketosulfone compound, a β-sulfonyl sulfone compound, or an α-diazocompound of a combination thereof. Specific examples of the sulfone compound include: 4-trisphenacyl sulfone, 2,4,6-mesityl phenacyl sulfone, bis(phenacylsulfonyl)methane or a combination thereof.

The sulfonic acid compound, for example, is an alkylsulfonic acid ester, a haloalkylsulfonic acid ester, an arylsulfonic acid ester or an iminosulfonate. Specific examples of the sulfonic acid compound include: benzoin tosylate (benzoin tosylate), pyrogallol tris(trifluoromethanesulfonate), o-nitrobenzyl trifluoromethanesulfonate, o-nitrobenzyl p-toluenesulfonate or a combination thereof.

Specific examples of the sulfonimide compound include: N-(trifluoromethylsulfonyloxy)succinimide, N-(trifluoromethylsulfonyloxy) phthalimide, N-(trifluoromethyl sulfonyloxy) diphenylmaleimide, N-(trifluoromethylsulfonyloxy) bicyclo[2.2.1]hept-5-ene-2,3-dicarboxyimide, N-(trifluoromethyl sulfonyloxy) naphthylimide, NAI-105 or a combination thereof.

The photoacid generator (B) is preferably 2,4-bis(trichloromethyl)-6-p-methoxystyryl-s-triazine, TAZ-110, the N-(trifluoromethyl sulfonyloxy) naphthylimide, NAI-105, triphenylsulfonium trifluoromethanesulfonate or a combination thereof.

Based on the usage amount of the novolac resin (A) being 100 parts by weight, a usage amount of the photoacid generator (B) is generally 0.1 to 5 parts by weight, preferably 0.3 to 5 parts by weight, and more preferably 0.5 to 4 parts by weight.

### Basic Compound (C)

The basic compound (C), for example, is an aliphatic primary amine, an aliphatic secondary amine, an aliphatic tertiary amine, an amino alcohol, an aromatic amine, a quaternary ammonium hydroxide, an alicyclic amine or a combination thereof. Specific examples of the basic compound (C) include: butylamine, hexylamine, ethanolamine, triethanolamine, 2-ethylhexylamine, 2-ethylhexyloxypropylamine, methoxy propylamine, diethylaminopropylamine, N-methylaniline, N-ethylaniline, N-propylaniline, dimethyl-N-methylaniline, diethyl-N-methylaniline, diisopropyl-N-dimethylaniline, N-methylamino phenol, N-ethylamino phenol, N,N-dimethylaniline, N,N-diethylaniline, N,N-dimethylamino phenol, tripentylamine, tetrabutylammonium hydroxide, tetramethylammonium hydroxide, 1,8-diazabicyclo[5.4.0]-7-undecene, 1,5-diazabicyclo[4.3.0]-5-nonene or a combination thereof.

The basic compound (C) is preferably tripentylamine, N-ethylaniline, N,N-dimethylamino phenol, tetramethylammonium hydroxide (TMAH), diethylaminopropylamine or a combination thereof.

If the negative photosensitive resin composition is unable to use the basic compound (C), then the obtained photoresist pattern formed by the negative photosensitive resin composition has a problem of having the poor strippability.

Based on the usage amount of the novolac resin (A) being 100 parts by weight, a usage amount of the basic compound (C) is generally 0.1 to 5 parts by weight, preferably 0.5 to 5 parts by weight, and more preferably 0.5 to 4 parts by weight.

### Cross-Linking Agent (D)

The cross-linking agent (D) is a compound for facilitating a formation of covalent bond or ionic bond between linear molecules, and may enable the linear molecules to be bonded with each other, thereby forming a polymer network. Noteworthily, the novolac resin (A) may react with the cross-linking agent (D) through the catalysis of the photoacid generator (B), so as to form a compound with a higher degree of crosslinking.

The cross-linking agent (D), for example, is an alkoxy methylated urea resin, an alkoxy methylated melamine resin, an alkoxy methylated uronresin, an alkoxy methylated glycoluryl resin or an alkoxy methylated amino resin.

In addition, the cross-linking agent (D), for example, is an alkyl etherified melamine resin, a benzoguanamine resin, an alkyl etherified benzoguanamine resin, a urea resin, an alkyl etherified urea resin, a urethane formaldehyde resins, a resol-type phenol-formaldehyde resin, an alkyl etherified resol-type phenol-formaldehyde resin or an epoxy resin.

Among the above-mentioned cross-linking agent, the alkoxy methylated amino resin is much preferred. Specific examples of the alkoxy methylated amino resin include: methoxy methylated amino resin, ethoxy methylated amino resin, n-propoxy methylated amino resin, n-butoxy methylated amino resin or a combination thereof. For instance, specific examples of commercially available products of the alkoxy methylated amino resin include: PL-1170, PL-1174, UFR 65, CYMEL 300, CYMEL 303 (above are manufactured by Sumitomo Cytec), BX-4000, NIKALAC MW-30, MX-290, MW-30HM, MS-11, MS-001, MX-750 or MX-706 (above are manufactured by Sanwa Chemicals) or a combination thereof.

The cross-linking agent (D) is preferably CYMEL 303, NIKALAC MW-30, PL-1170 or a combination thereof.

Based on the usage amount of the novolac resin (A) being 100 parts by weight, a usage amount of the cross-linking agent (D) is generally 5 to 50 parts by weight, preferably 7 to 45 parts by weight, and more preferably 10 to 40 parts by weight.

Solvent (E)

The solvent (E) used by the negative photosensitive resin composition is an organic solvent capable of dissolving the aforementioned compositions without causing a reaction.

The solvent (E), for example, is a (poly)alkylene glycol monoalkyl ether, a (poly)alkylene glycol monoalkyl ether acetate, an ether, a ketone, an alkyl lactate, an aromatic hydrocarbon, a lactam or a combination thereof.

Specific examples of the (poly)alkylene glycol monoalkyl ether include: ethylene glycol monomethyl ether, ethylene glycol monoethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether (PGEE), dipropylene glycol monomethyl ether, dipropylene glycol monoethyl ether, dipropylene glycol mono-n-propyl ether, dipropylene glycol mono-n-butyl ether, tripropylene glycol monomethyl ether, tripropylene glycol monoethyl ether or the like, or a combination thereof

Specific examples of the (poly)alkylene glycol monoalkyl ether acetate include: ethylene glycol monomethyl ether acetate, diethylene glycol monoethyl ether acetate, propylene glycol monomethyl ether acetate (PGMEA), propylene glycol monoethyl ether acetate or the like, or a combination thereof

Specific examples of the ether include: diethylene glycol dimethyl ether, diethylene glycol methyl ethyl ether, diethylene glycol diethyl ether, tetrahydrofuran or the like, or a combination thereof.

Specific examples of the ketone include: methyl ethyl ketone, cyclohexanone, 2-heptone, 3-heptone or the like, or a combination thereof.

Specific examples of the alkyl lactate include: methyl 2-hydroxy propionate, ethyl 2-hydroxy propionate (also known as ethyl lactate (EL)) or the like, or a combination thereof

Specific examples of the ester include: methyl 2-hydroxy-2-methyl propionate, ethyl 2-hydroxy-2-methyl propionate, methyl 3-methoxy propionate, ethyl 3-methoxy propionate, methyl 3-ethoxy propionate, ethyl 3-ethoxy propionate, ethyl ethoxy acetate, ethyl hydroxyl acetate, methyl 2-hydroxy-3-methyl butanoate, 3-methyl-3-methoxybutyl acetate, 3-methyl-3-methoxybutyl propionate, ethyl acetate, n-propyl acetate, i-propyl acetate, n-butyl acetate, i-butyl acetate, n-pentyl acetate, i-pentyl acetate, n-butyl propionate, ethyl butanoate, n-propyl butanoate, i-propyl butanoate, n-butyl butanoate, methyl pyruvate, ethyl pyruvate, n-propyl pyruvate, methyl acetoacetate, ethyl acetoacetate, ethyl 2-oxobutanoate or the like, or a combination thereof.

Specific examples of the aromatic hydrocarbon include: toluene, xylene or the like, or a combination thereof.

Specific examples of the lactam include: N-methyl pyrrolidone, N,N-dimethyl formamide, N,N-dimethyl acetamide or the like, or a combination thereof. The solvent (E) may be used alone or in multiple combinations. The solvent (E) is preferably propylene glycol monoethyl ether, dipropylene glycol monomethyl ether or ethyl lactate.

Based on the usage amount of the novolac resin (A) being 100 parts by weight, an usage amount of the solvent (E) is generally 100 to 1000 parts by weight, preferably 150 to 900 parts by weight, and more preferably 200 to 800 parts by weight.

### Additive (F)

The negative photosensitive resin composition of the invention may selectively be further added with an additive (F); specifically, the additive (F), for example, is an adhesion auxiliary agent, a leveling agent, a diluent or a sensitizer, or the like.

The adhesion auxiliary agent, for example, is a silane compound for increasing an adhesion property between the negative photosensitive resin composition and the substrate. Specific examples of the silane compound include: vinyltrimethoxysilane, vinyltriethoxysilane, 3-(methyl)acryloyloxypropyltrimethoxysilane (MPTMS), vinyltris(2-methoxyethoxy)silane, N-(2-aminoethyl)-3-aminopropylmethyldimethoxysilane, N-(2-aminoethyl)-3-aminopropyltrimethoxysilan), 3-aminopropyltriethoxysilane, 3-glycidoxypropyltrimethoxysilane, 3-glycidoxypropyldimethylmethoxysilane, 2-(3,4-epoxycyclohexyl) ethyltrimethoxysilane, 3-chloropropylmethyldimethoxysilane, 3-chloropropyltrimethoxysilane, 3-mercaptopropyltrimethoxysilane, 1,2-bis-(trimethoxysilyl)ethane or a combination thereof

In the specific examples of the invention, based on the usage amount of the novolac resin (A) being 100 parts by weight, a usage amount of the adhesion auxiliary agent is generally 0 parts by weight to 2 parts by weight, preferably 0.001 parts by weight to 1 parts by weight, and more preferably 0.005 parts by weight to 0.8 parts by weight.

The leveling agent may include a fluorine-based surfactant or a silicon-based surfactant. Specific examples of the fluorine-based surfactant include: commercially available Flourate FC-430, FC-431 (manufactured by 3M), F top EF122A, 122B, 122C, 126, BL20 (manufactured by Tochem Products Co., Ltd.) or a combination thereof. Specific examples of the silicon-based surfactant include: commercially available SF-8427, SH29PA (manufactured by Dow Corning Toray Silicone Co., Ltd.) or a combination thereof.

Based on the usage amount of the novolac resin (A) being 100 parts by weight, an usage amount of the surfactant is generally 0 parts by weight to 1.2 parts by weight, preferably 0.025 parts by weight to 1.0 parts by weight, and more preferably 0.050 parts by weight to 0.8 parts by weight.

Specific examples of the diluent include: commercially available RE801, RE802 (manufactured by TEIKOKU INK) or the like, or a combination thereof.

Specific examples of the sensitizer include: commercially available products of TPPA-1000P, TPPA-100-2C, TPPA-1100-3C, TPPA-1100-4C, TPPA-1200-24X, TP PA-1200-26X, TPPA-1300-235T, TPPA-1600-3M6C, TPPA-MF (manufactured by Honshu Chemical Industry Co., Ltd) or a combination thereof. The sensitizer is preferably the TPPA-600-3M6C or the TPPA-MF. The sensitizer may be used alone or in multiple combinations.

Based on the usage amount of the novolac resin (A) being 100 parts by weight, a usage amount of the sensitizer is generally 0 parts by weight to 20 parts by weight, preferably 0.5 parts by weight to 18 parts by weight, and more preferably 1.0 parts by weight to 15 parts by weight.

The additive (F) may be used alone or in multiple combinations. In addition, the invention may also be added with other additive, such as a plasticizer, a stabilizer or the like, according to the needs.

By disposing the novolac resin (A), the photoacid generator (B), the basic compound (C), the cross-linking agent (D) and the solvent (E) into a stirrer, the novolac resin (A), the photoacid generator (B), the basic compound (C), the cross-linking agent (D) and the solvent (E) are uniformly mixed into a solution state, so as to obtain the negative photosensitive resin composition; and the additive (F) may be added if necessary.

The negative photosensitive resin composition may be used to form the photoresist pattern. The photoresist pattern may be used as a pattern for forming a metallic pattern, and the metallic pattern may further be used as a metal electrode in a light emitting diode grain. In addition, in an organic light emitting diode display device, the photoresist pattern may also be used as a spacer on the substrate. Specifically, as follows:

### <Method for Forming Photoresist Pattern>

The negative photosensitive resin composition may be used to form the photoresist pattern. A method for forming a photoresist pattern is described in detail below, and the method includes: using the negative photosensitive resin composition to form the photoresist film; performing a patterned photoresist exposure to the photoresist film; and removing the unexposed region via an alkali development so as to form the photoresist pattern.

### —Forming Coating Film—

By using coating meanings such as a spin coating, a cast coating or a roll coating, the negative photosensitive resin composition of the solution state is uniformly coated on a substrate, so as to form a coating film. The substrate, for example, is a silicon substrate, a glass substrate, an indium tin oxide (ITO) film substrate, a chromium film formed substrate or a resin substrate.

After the coating film is formed, a majority portion of organic solvent of light cured polysiloxane compositions is removed through drying under reduced pressure, and then the residual organic solvent is completely removed via pre-baking, so as to form a photoresist film. In general, the pre-baking is to perform a heat treatment to the photoresist film under a temperature of 80° C. to 110° C. for 10 to 200 seconds. As a result, the photoresist film with a thickness of 0.5 to 5 microns may be obtained.

### —Patterned Photoresist Exposure—

The photoresist film is exposed with a mask having a specific pattern. In the present embodiment, the negative photosensitive resin composition is a cross-linking amplified resist material, and uses the photoacid generator (B) and the cross-linking agent (D) as cross-linking components. Therefore, after the photoresist film is being pattern exposed, the heat treatment is performed to the photoresist film under a temperature of 100° C. to 130° C. for 10 to 200 seconds, so as to increase a degree of cross-linking reaction.

A light used in the process of exposure is, for example, ultraviolet, far ultraviolet, KrF excimer laser beam or X ray. In particular, specific examples of the light used during the exposure include: line spectrums of 436 nm, 405 nm, 365 nm or 254 nm mercury and KrF excimer laser beam of 248 nm.

### —Development—

The exposed photoresist film is immersed in an alkali developing solution to remove the unexposed part of the photoresist film, so that the photoresist pattern may be formed on the substrate.

The alkaline aqueous solution is generally used as a developer. The alkali developing solution, for example, is a sodium hydroxide, a potassium hydroxide, a sodium silicate, ammonia or inorganic bases of the like; an ethylamine, a propylamine or primary amines of the like; a diethylamine, a propylamine or secondary amines of the like; a trimethylamine, a triethylamine or tertiary amines of the like; a diethylethanolamine, a triethanolamine or amino alcohols of the like; and a tetramethylammonium hydroxide, a tetraethylammoniumhydroxid, a triethylhydroxymethyl ammonium hydroxide, a trimethylhydroxyethylammonium hydroxide or quaternary ammonium hydroxides of the like. If required, a methyl alcohol, a ethyl alcohol, a propyl alcohol, a ethylene glycol or water-soluble organic solvents of the like; a surfactant; or a dissolution inhibitor of a resin may be added into the alkaline aqueous solution.

### <Method for Manufacturing Light Emitting Diode Grain>

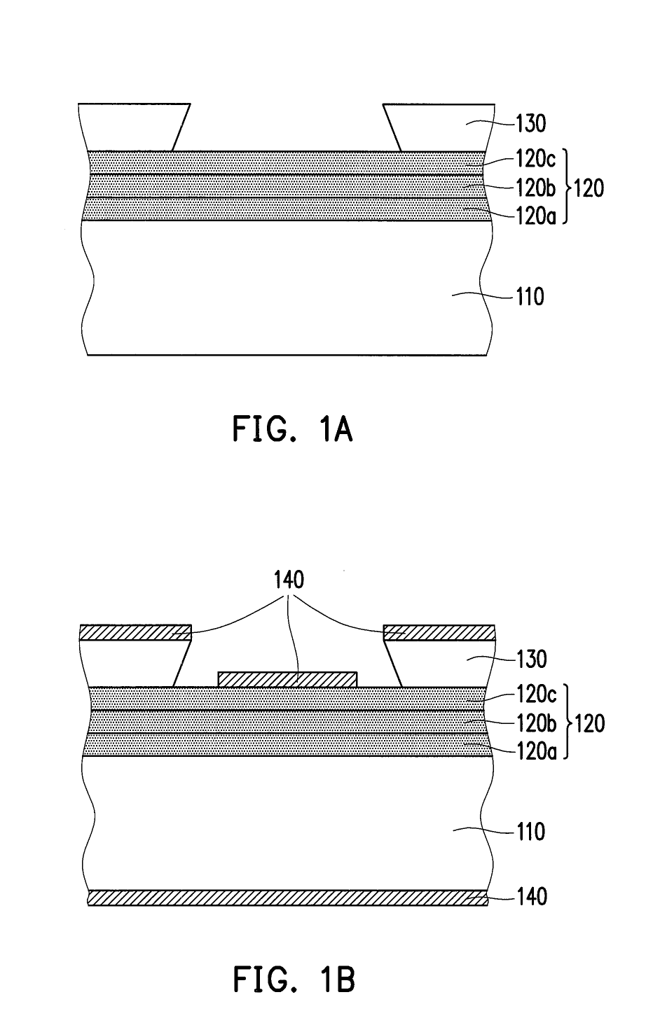

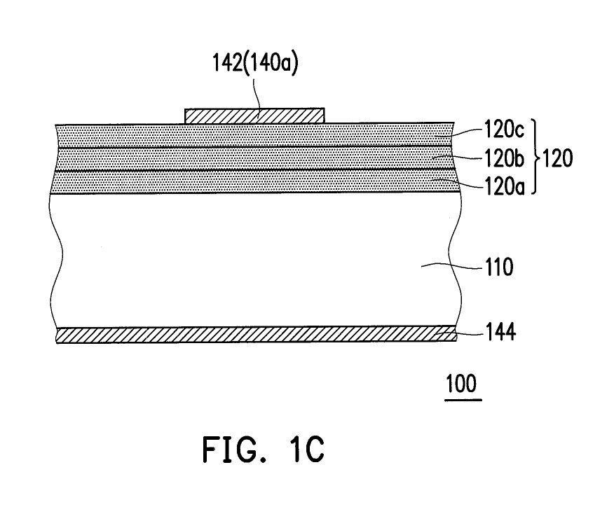

In the present embodiment, the negative photosensitive resin composition may be used to form the photoresist pattern as the pattern for forming the metal electrode of the light emitting diode grain. Specifically, a method for forming the light emitting diode grain is as shown in FIG. 1A to FIG. 1C.

Referring to FIG. 1A, firstly, a semiconductor layer 120 is formed on a substrate 110. In the present embodiment, the semiconductor layer 120 includes a N-type semiconductor layer 120a, an active layer 120b and a P-type semiconductor layer 120c, and the N-type semiconductor layer 120a, the active layer 120b and the P-type semiconductor layer 120c are sequentially disposed on the substrate 110. Next, a photoresist pattern 130 is formed on the semiconductor layer 120 by using the aforementioned method for forming the photoresist pattern. In the present embodiment, the photoresist pattern 130, for example, is in a shape of wide top and narrow bottom (viz., a reversed tapered shape).

Then, referring to FIG. 1B, metal layers 140 are respectively formed on two sides of the semiconductor layer 120 by using a sputtering, a deposition method or other appropriate methods, so that the metal layers 140 respectively cover on the substrate 110, the semiconductor layer 120 and the photoresist pattern 130. In addition, a material of the metal layers 140 may be gold, silver, aluminum, copper or other appropriate metal material.

Afterward, referring to FIG. 1C. The photoresist pattern 130 and the metal layer 140 located on the photoresist pattern 130 are removed by using a lift-off method, so as to perform a patterning to the metal layer 140, such that a metallic pattern 140a is formed on the semiconductor layer 120. Noteworthily, in the present embodiment, since the photoresist pattern 130 is in the shape of wide top and narrow bottom (viz., the reversed tapered shape), the metal layer 140 covering on the semiconductor layer 120 and the metal layer 140 covering on the photoresist pattern 130 are discrete, and are easily to be removed. In other embodiments, the photoresist pattern may also be designed into a shape of narrow top and wide bottom (viz. a forward tapered shape) or equal wide top and bottom (viz., vertical shape) according to the needs.

Noteworthily, the metallic pattern 140a located on the semiconductor layer 120 may be used as a first electrode layer 142, and the metal layer 140 located on the substrate 110 may be used as a second electrode layer 144. As a result, a light emitting diode grain 100 as shown in FIG. 1C may be formed. In addition, even though in the present embodiment that the second electrode layer 144 has not been patterned and is completely covered on the substrate 110, the designer may pattern the second electrode layer 144 according to the needs of the product.

### <Method for Manufacturing Organic Light Emitting Diode Display Device>

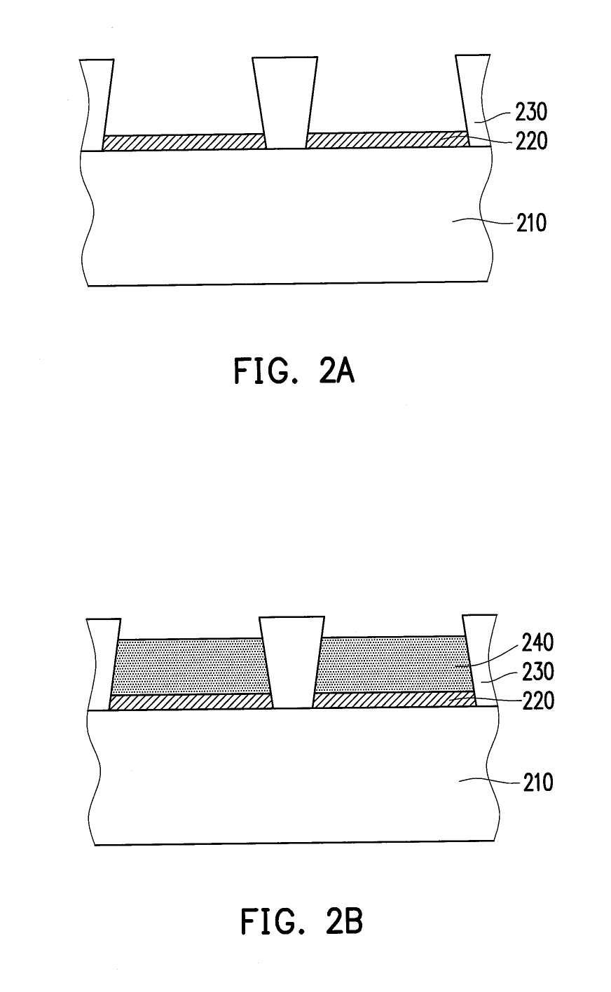

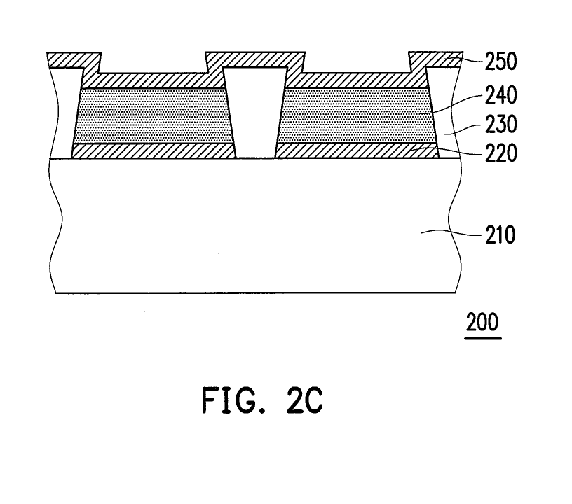

In the present embodiment, the photoresist pattern formed by the negative photosensitive resin composition may be used as the spacer, so as to form an organic light emitting diode display device. Specifically, a method for manufacturing the organic light emitting diode display device is as shown in FIG. 2A to FIG. 2C.

Referring to FIG. 2A, firstly, a first electrode layer 220 is formed on a substrate 210. According to an embodiment, the first electrode layer 220 is a plurality of electrode patterns, and a material thereof includes a metal oxide such as an indium tin oxide or the like. According to another embodiment, the first electrode layer 220 includes a plurality of electrode patterns and an active element electrically connected with the electrode patterns. A material of the electrode patterns includes a metal oxide such as an indium tin oxide or the like. The active element includes at least one thin film transistor.

Then, a spacer 230 is formed on the substrate 210. In the present embodiment, a method for forming the spacer 230, for example, is to use the method for forming the photoresist pattern described in above (paragraphs [0077-0083]). Herein, the spacer 230 is located at the periphery of the first electrode layer 220. In addition, in the present embodiment, the spacer 230 is in a reversed tapered shape. In other embodiments, the spacer 230 may also be designed into a forward tapered shape or vertical shape according to the needs.

Next, referring to FIG. 2B, organic materials are coated on a region defined by the spacer 230 via ink jet method, so as to form an organic layer 240. Noteworthily, the organic layer 240 may be a monolayer or multilayer structure; specifically, the organic layer 240 includes a light-emitting layer, a hole transporting material, a hole injecting material, an electron transporting material, an electron injecting material or a combination thereof.

Finally, referring to FIG. 2C, a metal layer is vapor deposited on the spacer 230 and a surface of the organic layer 240 via sputtering, evaporation, or other appropriate methods, so as to form a second electrode layer 250. As a result, the organic light emitting diode display device 200 shown in FIG. 2C may be formed.

### Synthesis Examples

### Synthesis example of novolac resin A-1-1

A nitrogen inlet, a stirrer, a heater, a condenser and a thermometer are configured on a 1000 ml four-necked Erlenmeyer flask, and the nitrogen is introduced. Next, 0.70 mole of m-cresol, 0.30 mole of p-cresol, 0.5 mole of 3,4-dihydroxybenzaldehyde and 0.020 mole of oxalic acid are added into the four-necked Erlenmeyer flask. Then, the reaction solution is stirred and heated to a temperature of 100° C., and further performed with a polycondensation under 100° C. for 6 hours. Next, the reaction solution is heated to 180° C., and then dried under a reduced pressure of 10 mmHg, so as to evaporate the solvent. Finally, a novolac resin (A-1-1) is obtained. Ingredient species and the usage amount of the novolac resin (A-1-1) are as shown in Table 1.

### Synthesis Examples of Novolac Resin A-1-2 to A-3-3

Synthesis methods of novolac resins A-1-2 to A-3-3 are the same as the novolac resin A-1-1, and differences lay in reactant species among the novolac resin (A-1), the usage amounts thereof, the reaction temperature and the polycondensation time. The reactant species, the usage amounts, the reaction temperature and the polycondensation time relative to the novolac resins A-1-2 to A-3-3 are as shown in Table 1.

Noteworthily, the novolac resins A-1-1 to A-1-3 are hydroxy-type novolac resins (A-1); the novolac resin A-2-1 to A-2-3 are xylenol-type novolac resins (A-2); and the novolac resins A-3-1 to A-3-3 are other novolac resins (A-3).

TABLE 1

| | | Synthesis Examples | | | | | | | | |
|---|---|---|---|---|---|---|---|---|---|---|
| | | A-1-1 | A-1-2 | A-1-3 | A-2-1 | A-2-2 | A-2-3 | A-3-1 | A-3-2 | A-3-3 |
| Aromatic | o-cresol | — | 0.10 | — | — | — | — | — | — | 0.05 |
| hydroxy | m-cresol | 0.70 | 0.40 | 0.40 | 0.40 | 0.35 | 0.50 | 0.70 | 0.50 | 0.65 |
| compound | p-cresol | 0.30 | 0.50 | 0.60 | 0.50 | 0.60 | 0.40 | 0.30 | 0.50 | 0.30 |
| (mol) | 3,5-dimethylphenol | — | — | — | — | 0.05 | — | — | — | — |
| | 3,4-dimethylphenoll | — | — | — | 0.10 | — | 0.05 | — | — | — |
| | 2,5-dimethylphenol | — | — | — | — | — | 0.05 | — | — | — |
| Aldehyde | 3,4-dihydroxy | 0.50 | — | 0.25 | — | — | — | — | — | — |
| (mol) | benzaldehyde | | | | | | | | | |
| | o-hydroxyl | — | 0.60 | — | — | — | — | — | — | — |
| | benzaldehyde | | | | | | | | | |
| | 2,3,4-trihydroxybenzaldehyde | — | — | 0.40 | — | — | — | — | — | — |
| | Formaldehyde | — | — | — | 0.65 | 0.70 | — | 0.70 | — | 0.65 |
| | Benzaldehyde | — | — | — | — | — | 0.65 | — | 0.60 | — |
| Catalyst | Oxalic acid | 0.020 | 0.015 | 0.020 | 0.020 | 0.020 | 0.020 | 0.015 | 0.020 | 0.020 |
| (mol) | | | | | | | | | | |

| | | | | | | | | | |
|---|---|---|---|---|---|---|---|---|---|
| Reaction temperature | 100 | 95 | 100 | 100 | 100 | 100 | 100 | 100 | 100 |
| (° C.) | | | | | | | | | |
| Polyethylene | 6 | 6 | 6 | 6 | 6 | 6 | 6 | 6 | 6 |
| polymerization time | | | | | | | | | |
| (hour) | | | | | | | | | |

### EMBODIMENTS

### Embodiment 1

40 parts by weight of novolac resin A-1-1, 60 parts by weight of novolac resin A-2-1, 0.1 parts by weight of TAZ-110, 0.1 parts by weight of tripentylamine and 5 parts by weight of CYMEL 303 are added into 100 parts by weight of propylene glycol monomethyl ether acetate (PGMEA), and after being stirred by a shaking type stirrer, a negative photosensitive resin composition of an embodiment 1 may obtained.

The negative photosensitive resin composition of the embodiment 1 is coated on a glass substrate via the spin coating, so as to form a coating film. Next, the coating film is pre-baked under 100° C. for 90 seconds to form a photoresist film with a thickness of approximately 3.4 μm. Then, the pattern exposure is performed to the pattern the photoresist film using ultraviolet light of 80mJ/cm² (Exposure Machine Model AG500-4N, manufactured by M&R Nanotechnology; and masks used are line and space masks (manufactured by NIPPON FILCON, JAPAN)). Next, the photoresist film is baked under a temperature of 110° C. for 2 minutes, so as to enhance the degree of crosslinking reaction. Subsequently, the substrate having the exposed photoresist film is developed for 1 minute using a 2.38% tetramethylammonium hydroxide (TMAH) aqueous solution at 23° C., so as to remove the unexposed portion of the photoresist film on the substrate. As a result, 100 cylinders (viz. semifinished products of the photoresist pattern) with a diameter of 20 μm may be obtained. Afterward, the glass substrate is washed with water. Finally, the semifinished products of the photoresist pattern are baked under 120° C. for 2 minutes in the oven, and thereby the photoresist pattern of the embodiment 1 may be obtained.

In addition, evaluations on strippability and degree of tolerance to evaporation process of the photoresist pattern formed by the negative photosensitive resin composition of the embodiment 1 are performed, and the results thereof are as shown in Table 3.

### Embodiment 2 to Embodiment 10

Negative photosensitive resin compositions and photoresist patterns of embodiment 2 to embodiment 10 are prepared by the same steps as the embodiment 1, and differences are that: the ingredient species and the usage amounts thereof are being changed (as shown in Table 3), wherein compounds corresponded by the labels in Table 3 are the same as the compounds in Table 2. In addition, evaluations on the strippability and the degree of tolerance to evaporation process of the photoresist patterns formed by the negative photosensitive resin compositions are performed, and the results thereof are as shown in Table 3.

TABLE 2

| | |
|---|---|
| B-1 | 2,4-bis(trichloromethyl)-6-p-methoxystyryl-s-triazine (TAZ-110) |
| B-2 | N-(trifluoromethyl sulfonyloxy) naphthylimide (NAI-105) |
| B-3 | triphenylsulfonium trifluoromethanesulfonate |
| C-1 | tripentylamine |
| C-2 | N-ethylaniline |
| C-3 | N,N-dimethylamino phenol |
| C-4 | tetramethylammonium hydroxide (TMAH) |
| C-5 | diethylaminopropylamine |
| D-1 | CYMEL 303 (manufactured by Mitsui SciTech Inc., alkoxy |
| | methylated amino resin) |
| D-2 | NIKALAC MW-30 (manufactured by SUNHO CHEMICAL |
| | CORP., alkoxy methylated amino resin) |
| D-3 | PL-1170 (manufactured by SUNHO CHEMICAL CORP., alkoxy |
| | methylated amino resin) |
| E-1 | propylene glycol monomethyl ether acetate (PGMEA) |
| E-2 | ethyl lactate (EL) |
| E-3 | propylene glycol monoethyl ether (PGEE) |
| F-1 | SF-8427 (manufactured by Dow Corning Toray, surfactant) |
| F-2 | 3-glycidoxypropyltrimethoxysilane (product name: KBM403, |
| | manufactured by Etsu Chemical; an adhesion auxiliary agent) |

### Comparative Example 1 to Comparative Example 6

Negative photosensitive resin compositions and photoresist patterns of comparative example 1 to comparative example 6 are prepared by the same steps as the embodiment 1, and differences are that: the ingredient species and the usage amounts thereof are being changed (as shown in Table 4), wherein compounds corresponded by the labels in Table 4 are the same as the compounds in Table 2. In addition, evaluations on the strippability and the degree of tolerance to evaporation process of the photoresist patterns formed by the negative photosensitive resin compositions are performed, and the results thereof are as shown in Table 4.

### <Evaluation Methods>

### [Strippability Evaluation]

The photoresist patterns (viz. cylinders) of the embodiments 2 to 10 and the comparative examples 1 to 6 are immersed in a lift-off solution (ST-897, manufactured by Chi Mei Corporation) of 70° C. for 3 minutes, so that the photoresist patterns (viz. cylinders) on the substrates are lifted-off. After performing the aforementioned process, amounts of residual cylinders on the substrates are being observed. In other words, a fewer amount of the residual cylinders presents a better strippability of the photoresist pattern (viz., the easier to be lifted-off). The strippabilities of the photoresist patterns are evaluated according to the following criteria:

◯: 0≦amount of the residual cylinders <10
X: 10≦amount of the residual cylinders

### [Tolerance to Evaporation Process Evaluation]

The photoresist patterns of the embodiments 2 to 10 and the comparative examples 1 to 6 are vapor deposited with a metal layer having a thickness of 5000 Å thereon through a vacuum evaporation machine (mode EVD-500, manufactured by Canon ANELVA). Next, amounts of damaged cylinders on the substrates are observed with a scanning electron microscope (SEM). In other words, a fewer the amount of damaged cylinders represents a better tolerance to the evaporation process of the photoresist pattern. The degrees of tolerance to evaporation process of the photoresist patterns evaluated according to the following criteria:

◯: 0≦amount of the damaged cylinders <10
Δ: 10≦amount of the damaged cylinders <20
X: 20≦amount of the damaged cylinders

### <Evaluation Results>

Referring to Table 3 and Table 4, the negative photosensitive resin composition of the comparative example 1 singly uses the novolac resin A-1-1 (viz. the hydroxy-type novolac resin (A-1)) without the xylenol-type novolac resin (A-2). The negative photosensitive resin composition of the comparative example 2 singly uses the novolac resin A-2-1 (viz. the xylenol-type novolac resin (A-2)) without the hydroxy-type novolac resin (A-1). According to the experimental results, the photoresist patterns of the comparative example 1 and the comparative example 2 have poor strippabilities and are also being intolerant to the evaporation process.

As in comparison, the negative photosensitive resin compositions of the embodiment 1 to embodiment 10 include the hydroxy-type novolac resins (A-1) and the xylenol-type novolac resins (A-2) at the same time, and the photoresist patterns of the embodiment 1 to the embodiment 10 have favorable strippabilities and are tolerant to the evaporation process. It can be known from this, that the photoresist patterns formed by the negative photosensitive resin compositions concurrently including the hydroxy-type novolac resin (A-1) and the xylenol-type novolac resin (A-2) have the favorable strippabilities and are tolerant to the evaporation process.

The negative photosensitive resin compositions of the comparative example 3 to the comparative example 6 do not have the basic compound (C), and the photoresist patterns of the comparative example 3 to the comparative example 6 have poor strippabilities.

As in comparison, the negative photosensitive resin compositions of the embodiment 1 to the embodiment 10 all include the basic compound (C), and the photoresist patterns of the embodiment 1 to the embodiment 10 have favorable strippabilities. It can be known from this, that the photoresist patterns formed by the negative photosensitive resin compositions including the basic compound (C) have the favorable strippabilities.

TABLE 3

| | | Embodiments | | | | | | | | | |
|---|---|---|---|---|---|---|---|---|---|---|---|
| Ingredients | | 1 | 2 | 3 | 4 | 5 | 6 | 7 | 8 | 9 | 10 |
| Novolac resin (A) | A-1-1 | 40 | | | 60 | | 40 | | 80 | | |
| (parts by weight) | A-1-2 | | 50 | | | | 40 | 70 | | 20 | |
| | A-1-3 | | | 60 | | 10 | | | | | 30 |
| | A-2-1 | 60 | | | | | | 30 | | 50 | |
| | A-2-2 | | 50 | | 30 | | 20 | | | 20 | |
| | A-2-3 | | | 40 | | 90 | | | 20 | | 60 |
| | A-3-1 | | | | | | | | | 10 | |
| | A-3-2 | | | | 10 | | | | | | |
| | A-3-3 | | | | | | | | | | 10 |
| Photoacid generator | B-1 | 0.1 | | | 4 | | 3 | 1 | 3 | | |
| (B) | B-2 | | 0.5 | | | 5 | | 1 | | 4 | |
| (parts by weight) | B-3 | | | 1 | | | 2 | | | | 5 |
| Basic compound (C) | C-1 | 0.1 | | | | | 1 | | | | |
| (parts by weight) | C-2 | | 0.5 | | | | | 2 | | | 5 |
| | C-3 | | | 1 | | | 1 | | 3 | 1 | |
| | C-4 | | | | 2 | | | 2 | 2 | | |
| | C-5 | | | | | 3 | | | | 1 | |
| Cross-linking agent | D-1 | 5 | | | | 20 | | | 10 | | 20 |
| (D) | D-2 | | 10 | | 20 | | 40 | 50 | 5 | 30 | |
| (parts by weight) | D-3 | | | 15 | | 10 | | | | | |
| Solvent (E) | E-1 | 100 | | 500 | | | 400 | | 500 | | 600 |
| (parts by weight) | E-2 | | 300 | | | 300 | | 300 | 200 | 1000 | |
| | E-3 | | | | 800 | | | 200 | | | |
| Additive (F) | F-1 | | 0.5 | | | | | | | | |
| (parts by weight) | F-2 | | | | | 2 | | | | | |

| | | | | | | | | | | |
|---|---|---|---|---|---|---|---|---|---|---|
| Strippability | ∘ | ∘ | ∘ | ∘ | ∘ | ∘ | ∘ | ∘ | ∘ | ∘ |
| Tolerance to evaporation | ∘ | ∘ | ∘ | ∘ | ∘ | ∘ | ∘ | ∘ | ∘ | ∘ |
| process | | | | | | | | | | |

TABLE 4

| | | Comparative Examples | | | | | |
|---|---|---|---|---|---|---|---|
| Ingredients | | 1 | 2 | 3 | 4 | 5 | 6 |
| Novolac resin (A) | A-1-1 | 100 | | | 80 | | |
| (parts by weight) | A-1-2 | | | 80 | | | |
| | A-1-3 | | | | | | |
| | A-2-1 | | 100 | 20 | | 70 | |
| | A-2-2 | | | | | | |
| | A-2-3 | | | | | | |
| | A-3-1 | | | | 20 | | 100 |
| | A-3-2 | | | | | 30 | |
| | A-3-3 | | | | | | |
| Photoacid generator | B-1 | 5 | 3 | | 3 | | 6 |
| (B) | B-2 | | | 5 | | | |
| (parts by weight) | B-3 | | | | | 3 | |
| Basic compound | C-1 | 1 | | | | | |
| (C) | C-2 | | 1 | | | | |
| (parts by weight) | C-3 | | | | | | |
| | C-4 | | | | | | |
| | C-5 | | | | | | |
| Cross-linking agent | D-1 | 10 | 15 | | | | 15 |
| (D) | D-2 | | | 10 | 10 | | |
| (parts by weight) | D-3 | | | | | 15 | |
| Solvent (E) | E-1 | 300 | | 300 | | 500 | |
| (parts by weight) | E-2 | | 300 | | 500 | | 300 |
| | E-3 | | | | | | |
| Additive (F) | F-1 | | | | | | |
| (parts by weight) | F-2 | | | | | | |

| | | | | | |
|---|---|---|---|---|---|
| Strippability | X | X | X | X | X |
| Tolerance to evaporation | X | Δ | X | X | X |
| process | | | | | |

In summary, the negative photosensitive resin composition of the invention by concurrently including the hydroxy-type novolac resin (A-1), the xylenol-type novolac resin (A-2) and the basic compound (C) may solve the problems of having a poor strippability between the photoresist pattern and the substrate, and the photoresist pattern being intolerant to the evaporation process, when the photoresist pattern is formed by the conventional negative photosensitive resin composition.

It will be apparent to those skilled in the art that various modifications and variations can be made to the structure of the application without departing from the scope or spirit of the application. In view of the foregoing, it is intended that the application cover modifications and variations of this application provided they fall within the scope of the following claims and their equivalents.

What is claimed is:

1. A negative photosensitive resin composition, comprising:
a novolac resin (A);
a photoacid generator (B);
a basic compound (C);
a cross-linking agent (D); and
a solvent (E),
wherein the novolac resin (A) comprises a hydroxy-type novolac resin (A-1) and a xylenol-type novolac resin (A-2), the hydroxy-type novolac resin (A-1) is synthesized by polycondensing a hydroxybenzaldehyde compound and an aromatic hydroxy compound, and the xylenol-type novolac resin (A-2) is synthesized by polycondensing an aldehyde compound and a xylenol compound.

2. The negative photosensitive resin composition as recited in claim 1, wherein the photoacid generator (B) comprises an onium salt compound, a halogen-containing compound, a sulfone compound, a sulfonic acid compound, a sulfonimide compound or a combination thereof.

3. The negative photosensitive resin composition as recited in claim 1, wherein the basic compound (C) comprises an aliphatic primary amine, an aliphatic secondary amine, an aliphatic tertiary amine, an amino alcohol, an aromatic amine, a quaternary ammonium hydroxide, an alicyclic amine, or a combination thereof.

4. The negative photosensitive resin composition as recited in claim 1, wherein based on 100 parts by weight of the novolac resin (A), a usage amount of the photoacid generator (B) is 0.1 to 5 parts by weight, an usage amount of the basic compound (C) is 0.1 to 5 parts by weight, an usage amount of the cross-linking agent (D) is 5 to 50 parts by weight, and an usage amount of the solvent (E) is 100 to 1000 parts by weight.

5. The negative photosensitive resin composition as recited in claim 4, wherein based on a total usage amount of the hydroxy-type novolac resin (A-1) and the xylenol-type novolac resin (A-2) being 100 weight %, an usage amount of the hydroxy-type novolac resin (A-1) is 10 weight % to 80 weight %, and an usage amount of the xylenol-type novolac resin (A-2) is 90 weight % to 20 weight %.

6. A method for forming a photoresist pattern, comprising:
coating a negative photosensitive resin composition as recited in claim 1 on a substrate; and
performing a processing step to the negative photosensitive resin composition so as to form a photoresist pattern.

7. The method for forming a photoresist pattern as recited in claim 6, wherein the photoresist pattern is a spacer.

8. A method for forming a metallic pattern, comprising:
forming a photoresist pattern on a substrate, wherein the photoresist pattern is formed by using the method as recited in claim 6;
forming a metal layer on the substrate and the photoresist pattern; and
removing the photoresist pattern and the metal layer located on the photoresist pattern so as to form a metallic pattern.

9. A method for manufacturing a light emitting diode grain comprising:
forming a semiconductor layer on a substrate; and
forming a metallic pattern on at least one side of the semiconductor layer for being an electrode layer, wherein the metallic pattern is formed by using the method as recited in claim 8.

10. A method for manufacturing an organic light emitting display device, comprising:
forming a first electrode layer on a substrate;
coating the negative photosensitive resin composition as recited in claim 1 on the substrate;
performing a processing step to the negative photosensitive resin composition so as to form a spacer;
forming an organic layer within a region defined by the spacer; and
forming a second electrode layer on the organic layer.
